(19) United States
(12) Patent Application Publication
(10) Pub. No.: US 2008/0315180 A1
(43) Pub. Date: Dec. 25, 2008

(54) SEMICONDUCTOR LIGHT EMITTING DEVICE

(76) Inventors: Kyung Jun Kim, Gwangju (KR); Hyo Kun Son, Gwangju (KR)

Correspondence Address: BIRCH STEWART KOLASCH & BIRCH, PO BOX 747, FALLS CHURCH, VA, 22040-0747, US

(21) Appl. No.: 12/145,155

(22) Filed: Jun. 24, 2008

(30) Foreign Application Priority Data
Jun. 25, 2007 (KR) 10-2007-0062040

(51) Int. Cl. H01L 33/00

(52) U.S. Cl. 257/13; 257/E33.008; 257/E33.027

(57) ABSTRACT

Provided is a semiconductor light emitting device. The semiconductor light emitting device comprises a first conductive type semiconductor layer, an active layer, and a second conductive type semiconductor layer. The active layer comprises a quantum barrier layer and a quantum well layer on the first conductive type semiconductor layer. An indium (In) composition ratio of the quantum well layer is changed in a graded manner. The second conductive type semiconductor layer is disposed on the active layer.

### CROSS-REFERENCE TO RELATED APPLICATIONS

The present application claims priority under 35 U.S.C. 126 and 35 U.S.C. 365 to Korean Patent Application No. 10-2007-0062040 (filed on Jun. 25, 2007), which is hereby incorporated by reference in its entirety.

### BACKGROUND

Groups III-V nitride semiconductors have been variously applied to an optical device such as blue and green light emitting diodes (LED), a high speed switching device, such as a MOSFET (Metal Semiconductor Field Effect Transistor) and an HEMT (Hetero junction Field Effect Transistors), and a light source of a lighting device or a display device.

The nitride semiconductor is mainly used for the LED (Light Emitting Diode) or an ID (laser diode), and studies have been continuously conducted to improve the manufacturing process or a light efficiency of the nitride semiconductor.

Embodiments provide a semiconductor light emitting device that can change a composition ratio(s) of indium (In) and/or aluminum (Al) contained in a quantum well layer and/or a quantum barrier layer of an active layer in a graded manner.

Embodiments provide a semiconductor light emitting device that that can adjust a composition ratio or a band gap of a material constituting at least one layer or all layers of an active layer in a graded manner.

Embodiments also provide a semiconductor light emitting device in which a composition ratio of a material constituting a portion layer of an active layer can be changed to compensate an energy band leaning due to a stress.

An embodiment provides a semiconductor light emitting device comprising: a first conductive type semiconductor layer; an active layer comprising a quantum barrier layer and a quantum well layer on the first conductive type semiconductor layer, wherein an indium (In) composition ratio of the quantum well layer is changed in a graded manner; and a second conductive type semiconductor layer on the active layer.

An embodiment provides a semiconductor light emitting device comprising: a first conductive type semiconductor layer; an active layer comprising at least one cycle of a quantum barrier layer and a quantum well layer on the first conductive type semiconductor layer, wherein an Al composition ratio of the quantum barrier layer is changed in a graded manner; and a second conductive type semiconductor layer on the active layer.

An embodiment provides a semiconductor light emitting device comprising: an n-type semiconductor layer; an active layer comprising a quantum barrier layer and a quantum well layer on the n-type semiconductor layer, wherein at least one of the quantum barrier layer and the quantum well layer has an approximately flat energy band by adjusting an In content or an Al content; and a p-type semiconductor layer on the active layer.

The details of one or more embodiments are set forth in the accompanying drawings and the description below. Other features will be apparent from the description and drawings, and from the claims.

### BRIEF DESCRIPTION OF THE DRAWINGS

FIG. 1 is a side cross-sectional view of a semiconductor light emitting device according to an embodiment.

FIG. 2A is an energy band diagram of an ideal active layer, and FIG. 2B is a diagram illustrating a deformation of an energy band of an active layer due to a stress.

FIG. 3 is an energy band diagram of an active layer according to a first embodiment.

FIG. 4 is an energy band diagram of an active layer according to a second embodiment.

FIG. 5 is an energy band diagram of an active layer according to a third embodiment.

FIG. 6 is an energy band diagram of an active layer according to a fourth embodiment.

FIG. 7 is an energy band diagram of an active layer according to a fifth embodiment.

FIG. 8 is an energy band diagram of an active layer according to a sixth embodiment.

FIG. 9 is a side cross-sectional view of a horizontal type semiconductor light emitting device using FIG. 1.

FIG. 10 is a side cross-sectional view of a vertical type semiconductor light emitting device using FIG. 1.

### DETAILED DESCRIPTION OF THE EMBODIMENTS

Hereinafter, a semiconductor light emitting device according to embodiments will be described with reference to the accompanying drawings.

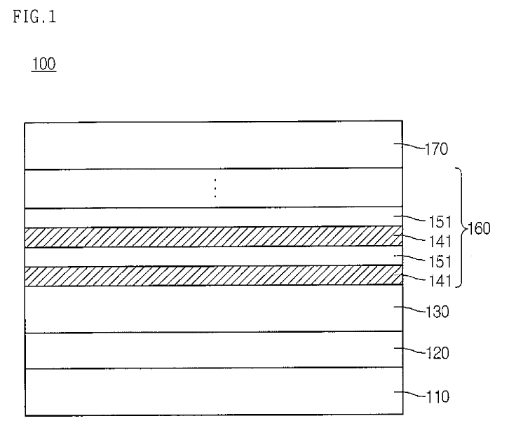

FIG. 1 is a side cross-sectional view of a semiconductor light emitting device according to an embodiment.

Referring to FIG. 1, a semiconductor light emitting device 100 comprises a substrate 110, a buffer layer 120, a first conductive type semiconductor layer 130, an active layer 160, and a second conductive type semiconductor layer 170.

The substrate 110 may be formed of at least one of sapphire (Al₂O₃), SiC, Si, GaAs, GaN, ZnO, GaP, InP, and Ge. Also, the substrate 110 may comprise a substrate having a conductive characteristic. A concave-convex pattern may be disposed on and/or under the substrate 110. The concave-convex pattern may have one of stripe, lens, cylindrical, and cone shapes.

A semiconductor thin film is grown on the substrate 110. Growth equipment may use an E-beam evaporator, a physical vapor deposition (PVD) apparatus, a chemical vapor deposition (CVD) apparatus, a plasma laser deposition (PLD) apparatus, a dual-type thermal evaporator, a sputtering apparatus, and a metal organic chemical vapor deposition (MOCVD) apparatus. However, the present disclosure is not limited to the equipment.

A buffer layer 120 may be disposed on the substrate 110. The buffer layer 120 mitigates lattice mismatch between the substrate 110 and the semiconductor thin film. The buffer layer 120 may be formed of at least one of GaN, InN, AlN, InGaN, AlGaN, InAlGaN, and AlInN.

An undoped semiconductor layer (not shown) may be disposed on the buffer layer 120. The undoped semiconductor layer may comprise an undoped GaN layer in which first conductive type dopants or second conductive type dopants are not added. The buffer layer 120 and/or the undoped semiconductor layer may be not provided on the substrate 110, and also, may not exist in a final device after thin film growth is completed.

The first conductive type semiconductor layer 130 is disposed on the buffer layer 130. The first conductive type semiconductor layer 130 may comprise at least one n-type semiconductor layer. The first conductive type semiconductor layer 130 serves as a first electrode contact layer. The first conductive type semiconductor layer 130 may be formed of at least one of GaN, InN, AlN, InGaN, AlGaN, InAlGaN, and AlInN. The first conductive type semiconductor layer 130 may be doped with the first conductive type dopants. The first conductive type dopants comprise n-type dopants and selectively comprises Si, Ge, Sn, Se, and Te.

For example, the first conductive type semiconductor layer 130 may comprise an n-type GaN layer having a predetermined thickness which is formed by supplying silane gas comprising n-type dopants such as NH₃, trimethyl gallium (TMGa) (or triethyl gallium (TEGa)), and Si.

The active layer 160 is disposed on the first conductive type semiconductor layer 130. The active layer 160 comprises a single quantum well structure or a multi-quantum well structure. The active layer 160 comprising the multi-quantum well structure will now be described for convenience.

The active layer 160 comprises a quantum well layer 141 and a quantum barrier layer 151. The active layer 160 comprises a cycle of the quantum well layer 141 and the quantum barrier layer 151 alternately stacked. The cycle of the quantum well layer 141 and the quantum barrier layer 151 may be repeated one time to twenty times, but the present disclosure is not limited thereto.

Although the quantum well layer 141 is first disposed on the first conductive type semiconductor layer 130 in the active layer 160, it may be changed, but the present disclosure is not limited thereto. The numbers of the quantum well layer 141 and the quantum barrier layer 151 may be equal to or different from each other, but the present disclosure is not limited thereto.

The quantum well layer 141 of the active layer 160 may be formed of indium (In), for example, may be formed of one of InGaN and InAlGaN. The quantum barrier layer 151 may be formed of aluminum (Al), for example, may be formed of one of AlGaN and InAlGaN. Also, the quantum barrier layer 151 may be formed of GaN.

The active layer 160 is formed of a material having an appropriate band gap energy depending on a desired light emission wavelength. For example, the quantum well/barrier layers 141 and 151 may comprise a cycle of InGaN/GaN layers, a cycle of InGaN/AlGaN layers, and a cycle of InAlGaN/InAlGaN layers. Also, the active layer 160 may be formed of different materials, for example, materials capable of emitting chromatic light such as orange light, yellow light, violet light, ultraviolet light, red light, and green light.

For example, the active layer 160 may comprise the quantum well layer 141 formed of InGaN and the quantum barrier layer 151 formed of GaN which are grown by supplying NH₃, TMGa (or TEGa), and trimethylindium (TMIn) as a source gas using H₂ and/or N₂ as a carrier gas at a predetermined growth temperature, e.g., a temperature ranging from about 700° C. to about 950° C. In case where the quantum barrier layer 151 is formed of AlGaN, trimethylaluminum (TMAl) gas may be additionally supplied as the source gas.

A composition ratio of In may be reduced in a graded manner in the quantum well layer 141 formed of In, and a composition ratio of Al may be reduced in a graded manner in the quantum barrier layer 151 formed of Al. The quantum well layer 141 having a changed In composition ratio may be applied to at least one layer or all layers. The quantum barrier layer 151 having a changed Al composition ratio may be applied to at least one layer or all layers.

Each quantum well layer 141 may have a thickness ranging from about 15 Å to about 30 Å, and each quantum barrier layer 151 may have a thickness ranging from about 50 Å to about 300 Å, but the present disclosure is not limited thereto.

At least one conductive type cladding layer (not shown) may be disposed on and/or under the active layer 160, but the present disclosure is not limited thereto.

The second conductive type semiconductor layer 170 is disposed on the active layer 160. The second conductive type semiconductor layer 170 may comprise a p-type semiconductor layer doped with p-type dopants. The p-type semiconductor layer may be formed of one of compound semiconductors such as GaN, InN, AlN, InGaN, AlGaN, InAlGaN, and AlInN. The p-type dopant may add at least one of Mg, Zn, Ca, Sr, and Ba.

A transparent electrode layer (not shown) may be disposed on the second conductive type semiconductor layer 170. The transparent electrode layer may be formed of one of ITO, ZnO, IrOx, RuOx, and NiO. In the semiconductor light emitting device 100, the first conductive type semiconductor layer 130 may be implemented as the n-type semiconductor layer, and the second conductive type semiconductor layer 170 may implemented as the p-type semiconductor layer, or may be implemented in reverse structure. Also, the n-type semiconductor layer or the p-type semiconductor layer may be disposed on the second conductive type semiconductor layer 170. Therefore, the semiconductor light emitting device 100 may comprise one structure of an N—P junction structure, a P—N junction structure, an N—P—N junction structure, and a P—N—P junction structure.

The In composition ratio of the InGaN quantum well layer 141 may be reduced in a graded manner as the InGaN quantum well layer 141 is grown according to a direction of the second conductive type semiconductor layer 170 or a growth time of the InGaN quantum well layer 141. The In composition ratio of the multi-quantum well layer 141 may be reduced in a graded manner in at least one layer or all layers. The InGaN quantum well layer 141 and the GaN or AlGaN quantum barrier layer 151 may be grown in one cycle. As a result, an energy band leaning due to a stress is compensated in the quantum well layer 141.

The Al composition ratio of the AlGaN quantum barrier layer 151 may be reduced in a graded manner as the AlGaN quantum barrier layer 151 is grown according to a direction of the second conductive type semiconductor layer 170 or a growth time of the AlGaN quantum barrier layer 151. The Al composition ratio of the multi-quantum barrier layer 151 may be reduced in a graded manner in at least one layer or all layers. The AlGaN quantum barrier layer 151 and the InGaN quantum well layer 141 may be grown in one cycle. As a result, an energy band leaning due to a stress is compensated in the quantum barrier layer 151.

The In and/or Al composition ratio(s) can be reduced in a graded manner in at least one layer or the all layers of the quantum well layer 141 and the quantum barrier layer 151. Thus, a deformation of the energy band due to the stress generated at a boundary between the quantum well layer 141 and the quantum barrier layer 151 can be compensated. That is, the quantum well layer 141 and the quantum barrier layer 151 can have an approximately flat band or a uniform band gap due to compensate the energy band leaning with the stress.

The active layer 160 can solve a limitation due to the deformation of the energy band, e.g., reduction of internal luminous efficiency, generation of excessive heat, or generation of light having a wavelength longer than that of a proper band gap.

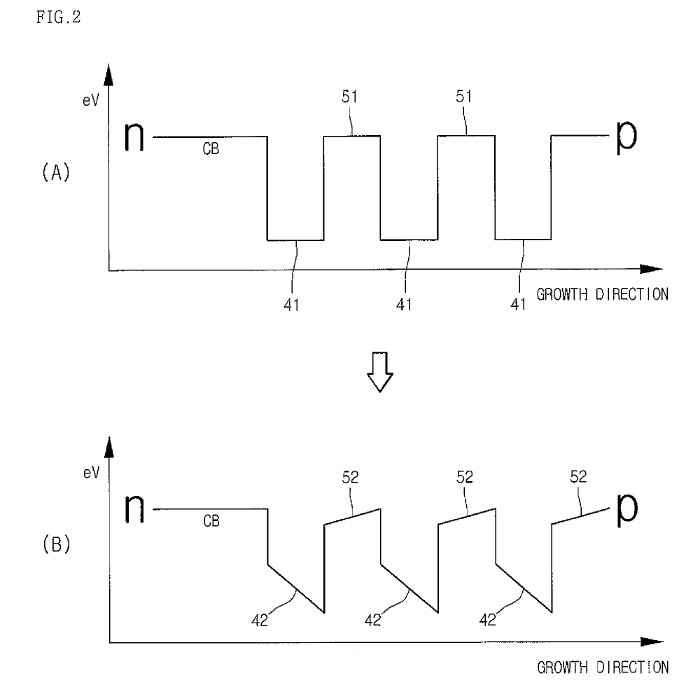

FIG. 2 is an energy band diagram of an active layer according to a comparative example and an example, FIG. 2A is an ideal energy band diagram of an active layer in a conduction band (CD), and FIG. 2B is a view of an actual band diagram after growth. Such FIG. 2 illustrates a deformation of an energy band in an active layer.

Referring to FIG. 2A, an ideal active layer is designed with a shape in which energy bands of an InGaN well layer 41 and a(n) (Al)GaN barrier layer 51 are flat. When the active layer is grown, lattice mismatch between an InGaN quantum well layer 42 and a(n) (Al)GaN quantum barrier layer 52 increases to generate a stress at a boundary between the InGaN quantum well layer 42 and the (Al)GaN quantum barrier layer 52. Energy bands of the InGaN quantum well layer 42 and the (Al)GaN quantum barrier layer 52 are respectively biased in any one direction due to the stress according to a growth time.

Referring to FIG. 2B, an energy band potential of the quantum well layer 42 has a sloped structure in which a potential of an n-type semiconductor layer side is high, and a potential of a p-type semiconductor layer side is low. Also, an energy band potential of the quantum barrier layer 52 has a sloped structure in which the potential of the n-type semiconductor layer side is low, and the potential of the p-type semiconductor layer side is high.

A piezoelectric field is generated toward a substrate in the active layer itself. When the piezoelectric field is generated (Epiezo≠0), a quantum confined stark effect (QCSE) occurs due to the piezoelectric field. As a result, internal luminous efficiency is reduced in the semiconductor light emitting device to emit light having a wavelength longer than that of a proper band gap.

A shape of the quantum well layer is deformed by a piezoelectric effect and the QCSE due to the stress. Carriers injected into the deformed quantum well layer are biased toward a lower position of the quantum well layer. Therefore, the internal luminous efficiency is reduced, and an excessive heat is generated to deteriorate reliability of the semiconductor light emitting device.

In the embodiment of FIG. 1, the biased energy band is compensated in the active layer 160 having a single or multi-quantum well structure to prevent the deformation of the energy band. For this, an energy band structure to be deformed is inversely designed in anticipation of the stress with respect to at least one layer or all layers of the active layer 160. Thus, the approximately flat energy band or the uniform band gap can be provided even if the deformation of the energy band is generated by the stress.

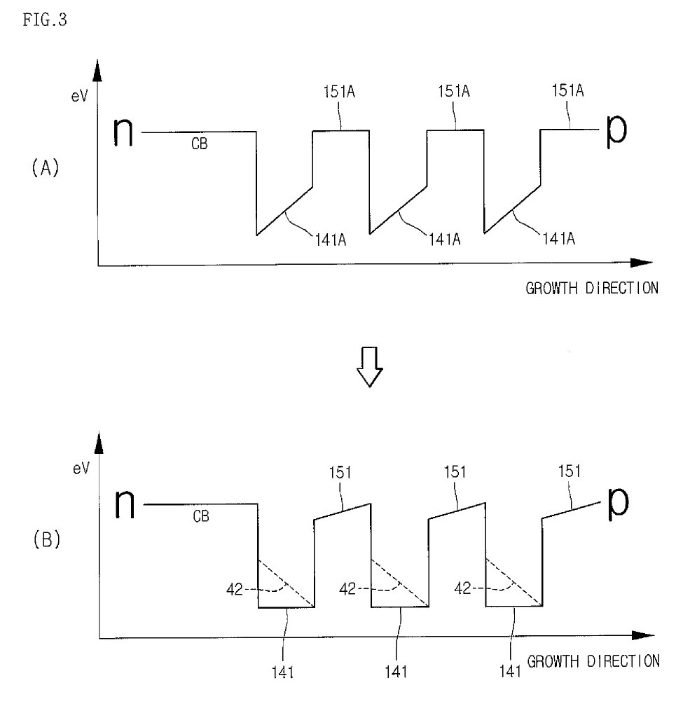

FIGS. 3 to 8 are energy band diagrams of an active layer according to first to sixth embodiments. Hereinafter, for convenience in description, a first conductive type semiconductor layer will be referred to as an n-type semiconductor layer or an n-side, a second conductive type semiconductor layer will be referred to as a p-type semiconductor layer or a p-side.

FIG. 3 is an energy band diagram of an active layer according to a first embodiment. FIG. 3A is a band diagram of an active layer designed in anticipation of a stress of a quantum well layer, and FIG. 3B is a band diagram after growing the active layer designed as illustrated in FIG. 3A.

Referring to FIG. 3A, a band diagram of a quantum well layer 141A is designed in anticipation of a quantum well layer 42 (dot line) to be deformed due to a stress as illustrated in FIG. 3B. That is, an energy band potential of the quantum well layer 141A is designed so that an n-type semiconductor layer side is low, and a p-type semiconductor layer side is high. Here, the energy band of the quantum well layer 141A may be designed so that the energy band potential of the n-type semiconductor layer side is lower than a reference potential, and the energy band potential of the p-type semiconductor layer side is equal to the reference potential.

A quantum barrier layer 151A is designed with a flat energy band.

Referring to FIG. 3B, an active layer is grown according to the band diagram designed as illustrated in FIG. 3A. In initial growth, a quantum well layer 141 of the active layer has a relatively high In content, and thereafter, the In content is reduced in a graded manner up to a reference amount during the growth. As a result, the quantum well layer 141 can have an energy band (or an approximately flat band) having uniform band gap. That is, in an energy band potential of the quantum well layer 141, the energy band potential of the n-type semiconductor layer side is equal to that of the p-type semiconductor layer side.

Each quantum well layer 141 is grown by changing InₐGa_{b}N/Inₐ₁Ga_{b1}N (0<a≦1, 0<a1≦1, b=1−a, b1=1−a1, a>a1) according to a growth time.

An In composition ratio of the InGaN quantum well layer 141 can be reduced in a graded manner to compensate an energy deformation due to a stress generated at a boundary between the InGaN quantum well layer 141 and the GaN or AlGaN quantum barrier layer 151A. Also, the quantum well layer 141 the approximately flat energy band or the uniform band gap can be applied to at least one layer or all layers of the quantum well layer 141.

A stress is applied to an energy band potential of a quantum barrier layer 151 so that the energy band potential of the n-type semiconductor layer side is low, and the energy band potential of the p-type semiconductor layer side is high.

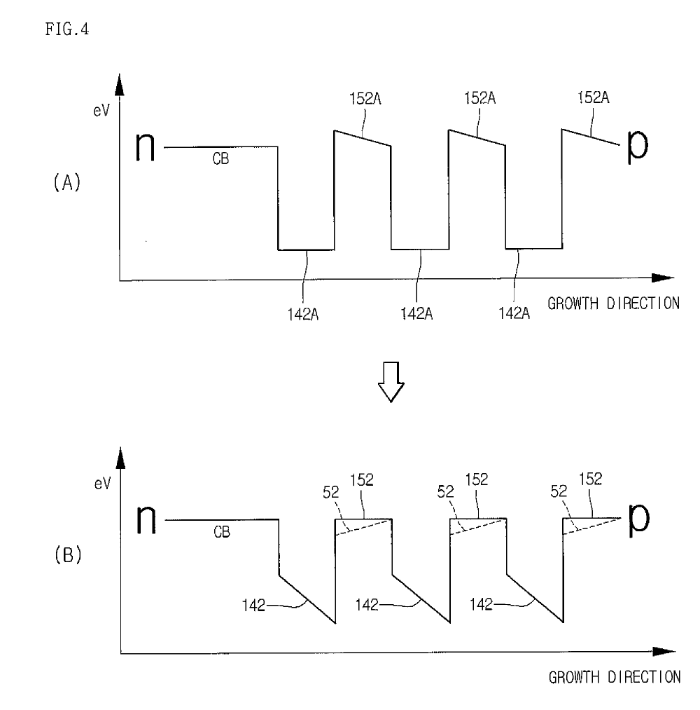

FIG. 4 is an energy band diagram of an active layer according to a second embodiment. FIG. 4A is a band diagram of an active layer designed in anticipation of a stress of a quantum barrier layer, and FIG. 4B is a band diagram after growing the active layer designed as illustrated in FIG. 4A.

Referring to FIG. 4A, a band diagram of a quantum barrier layer 152A is designed in anticipation of a quantum barrier layer (See reference numeral 52 of FIG. 4B) to be deformed due to a stress. That is, an energy band potential of the quantum barrier layer 152A is designed so that an n-type semiconductor layer side is high, and a p-type semiconductor layer side is low. A quantum well layer 142A is designed with a flat energy band.

Here, the energy band of the quantum barrier layer 152A may be designed so that the energy band potential of the n-type semiconductor layer side is higher than a reference potential, and the energy band potential of the p-type semiconductor layer side is equal to the reference potential.

Referring to FIG. 4B, an active layer is grown according to the band diagram designed as illustrated in FIG, 4A. In initial growth, a quantum barrier layer 152 of the active layer has a relatively high Al content, and thereafter, the Al content is reduced in a graded manner up to a reference amount during the growth. As a result, the quantum barrier layer 152 can have the approximately flat energy band or the uniform band gap.

A stress is applied to an energy band potential of a quantum well layer 142 so that the energy band potential of the n-type semiconductor layer side is high, and the energy band potential of the p-type semiconductor layer side is low.

The quantum well layer 142 is formed of InGaN. The quantum barrier layer 152 can be grown by changing Al_{c}Ga_{d}N/Al_{c1}Ga_{d1}N (0<c≦1, 0<c1≦1, d=1−c, d1=1−c1, c>c1) according to a growth time.

An Al composition ratio may be reduced in a graded manner according to the growth time to form the AlGaN barrier layer 152. Also, a cycle of Al_{c}Ga_{d}N/Al_{c1}Ga_{d1}N may be repeated to form the quantum barrier layer 152. Bending of the energy band due to the stress can be compensated in the quantum barrier layer 152.

Also, the quantum barrier layer 152 having an approximately flat energy band can be applied to at least one layer or all layers of the quantum barrier layer 152.

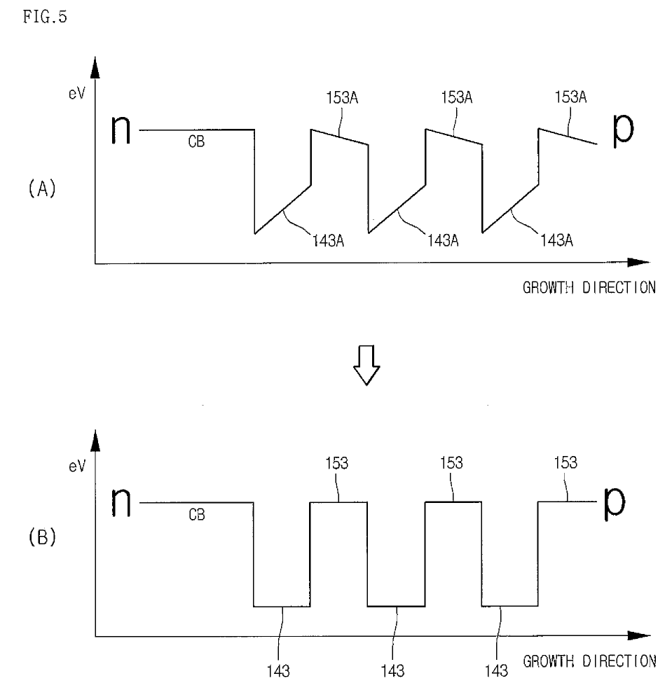

FIG. 5 is an energy band diagram of an active layer according to a third embodiment. FIG. 5A is a band diagram of an active layer designed in anticipation of stresses of a quantum well layer and a quantum barrier layer, and FIG. 5B is a band diagram after growing the active layer designed as illustrated in FIG. 5A.

Referring to FIG. 5A, a quantum well layer 143A and a quantum barrier layer 153A of an active layer are designed in anticipation of a deformation of an energy band due to a stress. The quantum well layer 143A is formed of InGaN. An energy band potential of the quantum well layer 143A is designed so that the energy band potential of an n-type semiconductor layer side is lower than that of a p-type semiconductor layer side. The quantum barrier layer 153A is formed of AlGaN. An energy band potential of the quantum barrier layer 153A is designed so that the energy band potential of an n-type semiconductor layer side is higher than that of a p-type semiconductor layer side. That is, the energy band potential of the quantum well layer 143A is designed so that the n-type semiconductor layer side is low with respect to the p-type semiconductor layer side. The energy band potential of the quantum barrier layer 153A is designed so that the n-type semiconductor layer side is high with respect to the p-type semiconductor layer side.

In the design of the energy band of the quantum well layer 143A and/or the quantum barrier layer 153A, although the p-type semiconductor layer side is designed as a reference potential, but it is one example. For example, a middle portion of the quantum well layer 143A or the quantum barrier layer 153A or the n-type semiconductor layer side is designed as the reference potential.

Referring to FIG. 5B, an active layer is grown according to the band diagram designed as illustrated in FIG. 5A. In initial growth, a quantum well layer 143 of the active layer has a relatively high In content, and thereafter, the In content is reduced in a graded manner up to a reference amount during the growth. As a result, the quantum well layer 143 can have the approximately flat energy band or the uniform band gap. That is, in the energy band of each quantum well layer 143, the energy band potential of the n-type semiconductor layer side is equal to that of the p-type semiconductor layer side.

The quantum well layer 143 is grown by changing InₐGa_{b}N/Inₐ₁Ga_{b1}N (0<a≦1, 0<a1≦1, b=1−a, b1=1−a1, a>a1) according to a growth time.

An In composition ratio of the InGaN quantum well layer 143 can be reduced in a graded manner to compensate an energy deformation due to a stress generated at a boundary between the InGaN quantum well layer 143 and the AlGaN quantum barrier layer 153. Also, the quantum well layer 143 having the approximately flat energy band or the uniform band gap can be applied to at least one layer or all layers of the quantum well layer 141.

In initial growth, a quantum barrier layer 153 of the active layer has a relatively high Al content, and thereafter, the Al content is reduced in a graded manner up to a reference amount during the growth. As a result, the quantum barrier layer 153 can have the approximately flat energy band or the uniform band gap.

The quantum barrier layer 153 can be grown by changing Al_{c}Ga_{d}N/Al_{c1}Ga_{d1}N (0<c≦1, 0<c1≦1, d=1−c, d1=1−c1, c>c1) according to a growth time. An Al composition ratio may be reduced in a graded manner according to the growth time to form the AlGaN barrier layer 153. Also, a cycle of Al_{c}Ga_{d}N/Al_{c1}Ga_{d1}N may be repeated to form the quantum barrier layer 153. Bending of the energy band due to the stress can be compensated in the quantum barrier layer 153. Also, the quantum barrier layer 153 having the approximately flat energy band or the uniform band gap can be applied to at least one layer or all layers of the quantum barrier layer 153.

The third embodiment can compensate the deformation of the energy band due to the stress in at least one cycle or all cycles comprising the cycle of the quantum barrier layer 153 and the quantum well layer 143 of the active layer.

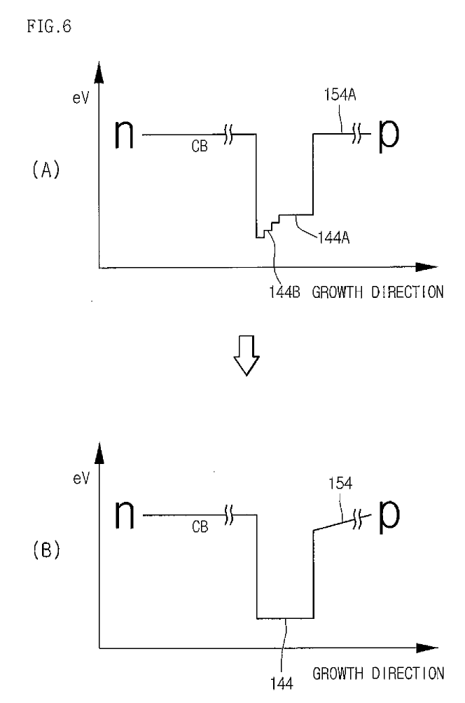

FIG. 6 is an energy band diagram of an active layer according to a fourth embodiment. The fourth embodiment will compensate a deformation of an energy band using a quantum well layer having a super lattice structure. FIG. 6A is a band diagram of an active layer designed in anticipation of stresses of a quantum well layer, and FIG. 6B is a band diagram after growing the active layer designed as illustrated in FIG. 6A.

Referring to FIG. 6A, a quantum well layer 144A of an active layer has a super lattice structure 144B. At least one layer or all layers of the quantum well layer 144A may have the super lattice structure 144B, but the present disclosure is not limited thereto.

An n-type semiconductor layer side of the quantum well layer 144A is grown in the super lattice structure 144B and in one cycle or more, and a p-type semiconductor layer side is grown in the super lattice structure 144B or a normal condition. The super lattice structure 144B of the quantum well layer 144A may be formed of InₐGa_{b}N/Inₐ₁Ga_{b1}N (0<a≦1, 0<a1≦1, b=1−a, b1=1−a1, a>a1).

The super lattice structure 144B of the quantum well layer 144A is grown in order of from a material having a small band gap to a material having a large band gap. Here, the material having the large band gap is a material having a low In content, and the material having the small band gap is a material having high In content.

A quantum barrier layer 154A of the active layer may be formed of AlGaN or GaN and be designed with a flat energy band potential.

Referring to FIG. 6B, an active layer is grown according to the band diagram designed as illustrated in FIG. 6A. In initial growth, a quantum well layer 144 of the active layer may be grown in a cycle of an InₐGa_{b}N/Inₐ₁Ga_{b1}N super lattice structure (See reference numeral 144B of FIG. 6A) and in one cycle or more, and thereafter, may be grown in the normal condition or the above-described super lattice structure. The InₐGa_{b}N/Inₐ₁Ga_{b1}N super lattice structure is grown in order of from the material having the small band gap to the material having the large band gap. That is, the InₐGa_{b}N/Inₐ₁Ga_{b1}N super lattice structure is grown in order of InₐGa_{b}N and Inₐ₁Ga_{b1}N (0<a1<a≦1).

In the InGaN quantum well layer 144A, a deformation of the energy band of the quantum well layer 144 can be compensated using a characteristic in which a band gap is changed according to the In content.

The quantum well layer 144 can have the approximately flat energy band or the uniform band gap because the deformation of the energy band thereof can be compensated.

The active layer according to the forth embodiment may comprise the quantum well layer 144 having the super lattice structure and selectively comprise the quantum well layer as described in the first embodiment and/or the quantum barrier layer as described in the second embodiment.

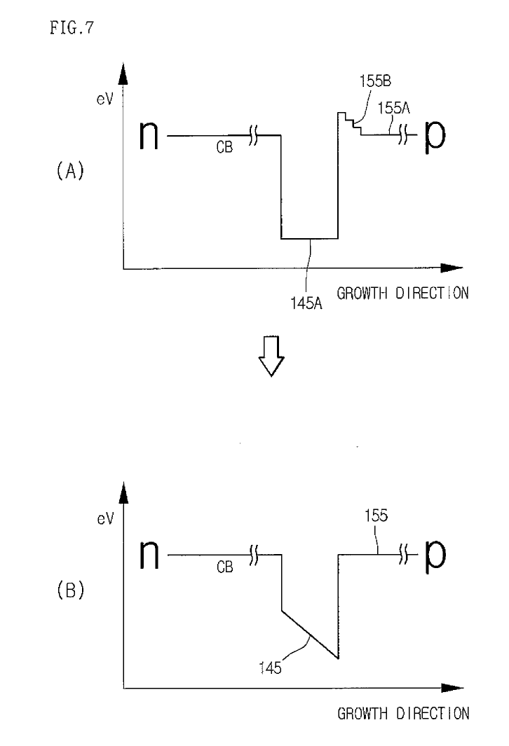

FIG. 7 is an energy band diagram of an active layer according to a fifth embodiment. The fifth embodiment will compensate a deformation of an energy band using a quantum barrier layer having a super lattice structure. FIG. 7A is a band diagram of an active layer designed in anticipation of stresses of a quantum barrier layer, and FIG. 7B is a band diagram after growing the active layer designed as illustrated in FIG. 7A.

Referring to FIG. 7A, a quantum barrier layer 155A of an active layer has a super lattice structure 155B. At least one layer or all layers of the quantum barrier layer 155A may have the super lattice structure 155B, but the present disclosure is not limited thereto.

An n-type semiconductor layer side of the quantum barrier layer 155A is grown in the super lattice structure 155B and in one cycle or more, and a p-type semiconductor layer side is grown in the super lattice structure 155B or a normal condition. Here, super lattice structure 155B is grown in a cycle of Al_{c}Ga_{d}N/Al_{c1}Ga_{d1}N (0<c≦1, 0<c1≦1, d=1−c, d1=1−c1, c>c1).

The super lattice structure 155B of the quantum barrier layer 155A may be grown in order of from a material having a large band gap to a material having a small band gap. Here, the material having the large band gap is a material having a high Al content, and the material having the small band gap is a material having low Al content.

Referring to FIG. 7B, an active layer is grown according to the band diagram designed as illustrated in FIG. 7A. In initial growth, a quantum barrier layer 155 of the active layer may be grown in a cycle of an Al_{c}Ga_{d}N/Al_{c1}Ga_{d1}N super lattice structure and in one cycle or more, and thereafter, may be grown in the normal condition or the above-described super lattice structure. The Al_{c}Ga_{d}N/Al_{c1}Ga_{d1}N super lattice structure of the quantum barrier layer 155 is grown in order of from the material having the large band gap to the material having the small band gap. That is, the Al_{c}Ga_{d}N/Al_{c1}Ga_{d1}N super lattice structure is grown in order of Al_{c}Ga_{d}N having the large band gap and Al_{c1}Ga_{d1}N having the small band gap (c>c1).

As a result, the quantum barrier layer 155 can have an approximately flat energy band or the uniform band gap because the deformation of the energy band thereof can be compensated. The deformation of the energy band due to the stress can be prevented or minimized in the quantum barrier layer 155.

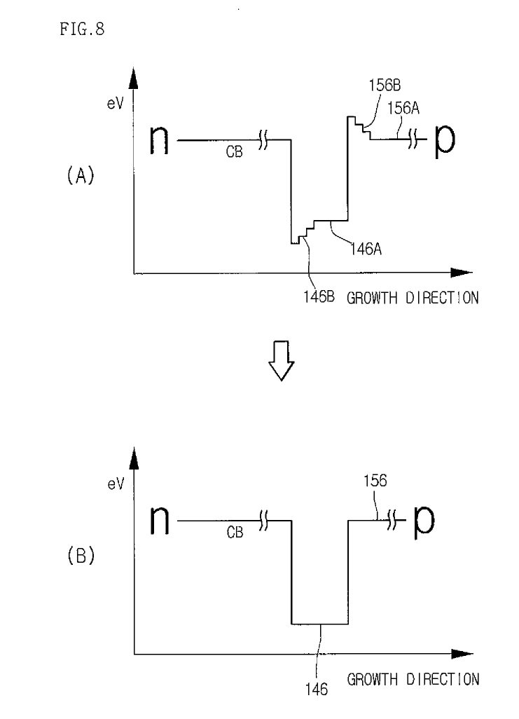

FIG. 8 is an energy band diagram of an active layer according to a sixth embodiment. The sixth embodiment will compensate a deformation of an energy band using a quantum well layer and a quantum barrier layer of a super lattice structure. FIG. 8A is a band diagram of an active layer designed in anticipation of stresses of a quantum well layer and a quantum barrier layer, and FIG. 8B is a band diagram after growing the active layer designed as illustrated in FIG. 8A.

Referring to FIG. 8A, a quantum well layer 146A of an active layer may be grown in a first super lattice structure 146B in a partial region or all region. The quantum barrier layer 156A may be grown in a second super lattice structure 156B in a partial region or all region. The first and second super lattice structures 146B and 156B may be grown in one cycle or more.

The first super lattice structure 146B comprises an InₐGa_{b}N/Inₐ₁Ga_{b1}N super lattice structure, and the second lattice structure 156B comprises an Al_{c}Ga_{d}N/Al_{c1}Ga_{d1}N super lattice structure.

The first super lattice structure 146B of the quantum well layer 146A is disposed toward an n-type semiconductor layer, and a p-type semiconductor layer side is grown in the first super lattice structure 146B or a normal condition. The second super lattice structure 156B of the quantum barrier layer 156A is disposed toward the n-type semiconductor layer, and the p-type semiconductor side is grown in the second super lattice structure 156B or the normal condition.

The first super lattice structure 146B of the quantum well layer 146A may be grown in order of from a material having a small band gap to a material having a large band gap. The second super lattice structure 156B of the quantum barrier layer 156A may be grown in order of from the material having the small band gap to the material having the large band gap. Here, as an In content increases, the band gap decreases, and as the In content decreases, the band gap increases.

Referring to FIG. 8B, in initial growth, a quantum well layer 146 of the active layer may be grown in a cycle of InₐGa_{b}N/Inₐ₁Ga_{b1}N of the first super lattice structure (See reference numeral 146B of FIG. 8A) and in one cycle or more, and thereafter, may be grown in the normal condition or the first super lattice structure. The InₐGa_{b}N/Inₐ₁Ga_{b1}N super lattice structure of the quantum well layer 146 is grown in order of from the material having the small band gap to the material having the large band gap. That is, the InₐGa_{b}N/Inₐ₁Ga_{b1}N super lattice structure is grown in order of from InₐGa_{b}N (0<a1<a≦1) to Inₐ₁Ga_{b1}N (0<a1<a≦1).

In the InGaN quantum well layer 146, a deformation of the energy band of the quantum well layer 146 can be compensated using a characteristic in which a band gap is changed according to the In content.

The quantum well layer 146 can have the approximately flat energy band or the uniform band gap because the deformation of the energy band thereof can be compensated.

Also, in initial growth, a quantum barrier layer 156 of the active layer may be grown in a cycle of Al_{c}Ga_{d}N/Al_{c1}Ga_{d1}N of the second super lattice structure and in one cycle or more, and thereafter, may be grown in the normal condition or the above-described super lattice structure. The Al_{c}Ga_{d}N/Al_{c1}Ga_{d1}N super lattice structure of the quantum barrier layer 156 is grown in order of from the material having the large band gap to the material having the small band gap. That is, the Al_{c}Ga_{d}N/Al_{c1}Ga_{d1}N super lattice structure is grown in order of from Al_{c}Ga_{d}N (0≦c1<c≦1) having the large band gap to Al_{c1}Ga_{d1}N (0≦c1<c≦1) having the small band gap. Here, in the AlGaN quantum barrier layer 156, the material having the large band gap is a material having a high Al content, and the material having the small band gap is a material having low Al content.

As a result, the quantum barrier layer 156 can have the approximately flat energy band or the uniform band gap because the deformation of the energy band thereof can be compensated. The deformation of the energy band due to the stress can be prevented or minimized in the quantum barrier layer 156.

In the first to sixth embodiments, a composition ratio of at least one of In, Al, and Ga is adjusted in at least one layer or all layers of the quantum well layer and/or the quantum barrier layer of the active layer to previously deform the energy band, thereby providing an approximately flat energy band to the quantum well layer and/or the quantum barrier layer even if the energy band deformation occurs due to the stress.

Also, by preventing the piezoelectric field due to the stress from being generated in the active layer, electrons and holes are gathered in a middle of the quantum well to evaluate probability for generation of pairs of electrons and holes, thereby improving the luminous efficiency. In addition, reduction of the internal luminous efficiency can be prevented, and light having a wavelength corresponding to a proper band gap can be emitted.

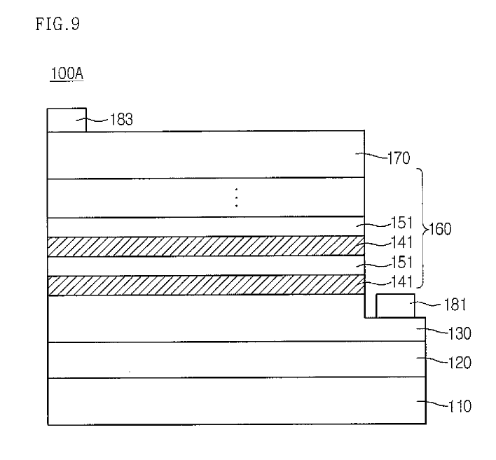

FIG. 9 is a side cross-sectional view of a horizontal type semiconductor light emitting device using FIG. 1. In a description of FIG. 9, a description of portions duplicated with those in FIG. 1 will be omitted.

Referring to FIG. 9, a semiconductor light emitting device 100A comprises a horizontal type semiconductor light emitting device. A first electrode 181 is disposed on a first conductive type semiconductor layer 130. A second electrode 183 is disposed on a second conductive type semiconductor layer 170. An n-type semiconductor layer and/or a transparent electrode layer may be disposed on the second conductive type semiconductor layer 170, and then, the second electrode 183 may be disposed on the n-type semiconductor layer and/or the transparent electrode layer.

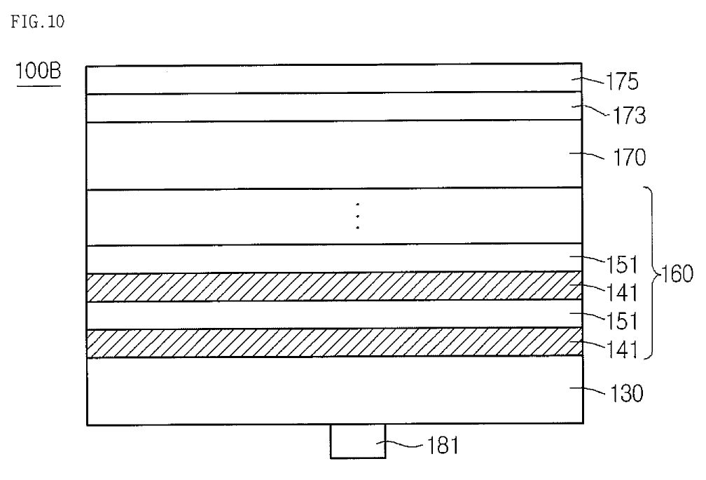

FIG. 10 is a side cross-sectional view of a vertical type semiconductor light emitting device using FIG. 1. In a description of FIG. 10, a description of portions duplicated with those in FIG. 1 will be omitted.

Referring to FIG. 10, a semiconductor light emitting device 100B comprises a vertical type semiconductor light emitting device. A reflective electrode layer 173 is disposed on a second conductive type semiconductor layer 170. A conductive supporting substrate 175 is disposed on the reflective electrode layer 173. The reflective electrode layer 173 is formed of one of Al, Ag, Pd, Rh, and Pt. The conductive supporting substrate 175 may be formed of copper and gold, but the present disclosure is not limited thereto.

The substrate 110 and the buffer layer 120 of FIG. 1 are removed using a physical and/or chemical removing method.

In the physical removing method, a laser beam having a predetermined wavelength is irradiated onto the substrate 110 to remove the substrate 110. The buffer layer 120 may be removed using a wet etch method or a dry etch method. In the chemical removing method, an etching solution may be injected into the buffer layer 120 to separate the substrate 110. The buffer layer may not be removed according to electrical properties. A first electrode 181 may be disposed under a first conductive type semiconductor layer 130.

In the embodiments, the deformation of the energy band due to the stress within the active layer can be compensated. At least one quantum well layer and/or quantum barrier layer having the approximately flat energy band can be provided. Also, the generation of the piezoelectric field can be prevented in the active layer, and the electrons and the holes can be gathered in the middle of the quantum well to evaluate the probability for generation of pairs of electrons and the holes, thereby improving the luminous efficiency. In addition, reduction of the internal luminous efficiency can be prevented, and light having a wavelength corresponding to a proper band gap can be emitted. Also, the reliability of the semiconductor light emitting device can be improved.

Although a compound semiconductor light emitting device comprising a N—P junction structure is used in the embodiments, the present disclosure is not limited thereto. For example, a compound semiconductor light emitting device comprising N—P—N, P—N, P—N—P junction structures may be used. In descriptions of the embodiments, it will be understood that when a layer (or film), a region, a pattern, or components is referred to as being ‘on’ or ‘under’ another substrate, layer (or film), region, or patterns, it can be directly on the other layer or substrate, or intervening layers may also be present. Also, in the descriptions of the embodiments, sizes of elements illustrated in drawings are one example, and the present disclosure is not limited to the illustrated drawings.

Any reference in this specification to “one embodiment,” “an embodiment,” “example embodiment,” etc., means that a particular feature, structure, or characteristic described in connection with the embodiment is comprised in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A semiconductor light emitting device comprising:
a first conductive type semiconductor layer;
an active layer comprising a quantum barrier layer and a quantum well layer on the first conductive type semiconductor layer, wherein an indium (In) composition ratio of the quantum well layer is changed in a graded manner; and
a second conductive type semiconductor layer on the active layer.

2. The semiconductor light emitting device according to claim 1, wherein the active layer comprises a single quantum well structure or a multi-quantum well structure.

3. The semiconductor light emitting device according to claim 1, wherein the quantum well layer is formed of InGaN, and the In composition ratio (Inₐ) is reduced in a graded manner (0<a≦1).

4. The semiconductor light emitting device according to claim 1, wherein the In composition ratio of a first conductive type semiconductor layer side is higher than that of a second conductive type semiconductor layer side in the quantum well layer.

5. The semiconductor light emitting device according to claim 1, wherein the quantum well layer is grown in a cycle of InₐGa_{b}N and Inₐ₁Ga_{b1}N (0<a≦1, 0<a1≦1, b=1−a, b1=1−a1, a>a1).

6. The semiconductor light emitting device according to claim 1, wherein the quantum well layer is grown in order of from a material having a small band gap to a material having a large band gap and in one cycle or more.

7. The semiconductor light emitting device according to claim 1, wherein the quantum barrier layer is formed of one of AlGaN and GaN.

8. The semiconductor light emitting device according to claim 1, wherein the quantum barrier layer is formed of AlGaN, and an aluminum (Al) composition ratio (Al_{c}) of the AlGaN quantum barrier layer is reduced in a graded manner (0<c≦1).

9. The semiconductor light emitting device according to claim 1, wherein the quantum barrier layer is grown in a cycle of Al_{c}Ga_{d}N and Al_{c1}Ga_{d1}N (0<c≦1, 0<c1≦1, d=1−c, d1=1−c1, c>c1) and in one cycle or more.

10. A semiconductor light emitting device comprising:
a first conductive type semiconductor layer;
an active layer comprising at least one cycle of a quantum barrier layer and a quantum well layer on the first conductive type semiconductor layer, wherein an Al composition ratio of the quantum barrier layer is changed in a graded manner; and
a second conductive type semiconductor layer on the active layer.

11. The semiconductor light emitting device according to claim 10, wherein the quantum barrier layer is formed of at least AlGaN, and the Al composition ratio (Al_{c}) of the AlGaN quantum barrier layer is reduced in a graded manner (0<c≦1).

12. The semiconductor light emitting device according to claim 10, wherein the quantum well layer is formed of InGaN, and the In composition ratio (Inₐ) of the InGaN quantum well layer is reduced in a graded manner (0<a≦1).

13. The semiconductor light emitting device according to claim 10, wherein the quantum barrier layer is grown in a cycle of Al_{c}Ga_{d}N and Al_{c1}Ga_{d1}N (0<c≦1, 0<c1≦1, d=1−c, d1=1−c1, c>c1).

14. The semiconductor light emitting device according to claim 10, wherein the quantum well layer is grown in a cycle of InₐGa_{b}N and Inₐ₁Ga_{b1}N (0<a≦1, 0<a1≦1, b=1−a, b1=1−a1, a>a1), and the quantum barrier layer is grown in a cycle of Al_{c}Ga_{d}N and Al_{c1}Ga_{d1}N (0<c≦1, 0<c1≦1, d=1−c, d1=1−c1, c>c1).

15. A semiconductor light emitting device comprising:
an n-type semiconductor layer;
an active layer comprising a quantum barrier layer and a quantum well layer on the n-type semiconductor layer, wherein at least one of the quantum barrier layer and the quantum well layer has an approximately flat energy band by adjusting an In content or an Al content; and
a p-type semiconductor layer on the active layer.

16. The semiconductor light emitting device according to claim 15, wherein the quantum well layer is formed of InGaN, an In composition ratio (Inₐ) of the InGaN quantum well layer is reduced in a graded manner up to a reference amount (0<a≦1).

17. The semiconductor light emitting device according to claim 15, wherein the quantum barrier layer is formed of AlGaN, and an Al composition ratio (Al_{c}) of the AlGaN quantum barrier layer is reduced in a graded manner up to a reference amount (0<c≦1).

18. The semiconductor light emitting device according to claim 15, wherein the quantum well layer is grown in a cycle of InₐGa_{b}N and Inₐ₁Ga_{b1}N (0<a≦1, 0<a1≦1, b=1−a, b1=1−a1, a>a1) and in one cycle or more, and the quantum barrier layer is grown in a cycle of Al_{c}Ga_{d}N and Al_{c1}Ga_{d1}N (0<c≦1, 0<c1≦1, d=1−c, d1=1−c1, c>c1) and in one cycle or more.

19. The semiconductor light emitting device according to claim 15, wherein at least one quantum well layer of the active layer has an approximately flat energy band by adjusting the In content.

20. The semiconductor light emitting device according to claim 15, wherein at least one quantum barrier layer of the active layer has an approximately flat energy band by adjusting the Al content.
